(19) United States
(12) Patent Application Publication
(10) Pub. No.: US 2020/0001423 A1
(43) Pub. Date: Jan. 2, 2020

(54) POWER POLISHING APPARATUSES AND METHODS FOR IN-SITU FINISHING AND COATING OF OPTICAL COMPONENT

(71) Applicant: Edmund Optics, Inc., Barrington, NJ (US)

(72) Inventors: Joel Bagwell, Voorhees, NJ (US); Nathan Carlie, Cherry Hill, NJ (US)

(73) Assignee: Edmund Optics, Inc., Barrington, NJ (US)

(21) Appl. No.: 16/212,035

(22) Filed: Dec. 6, 2018

Related U.S. Application Data
(60) Provisional application No. 62/690,514, filed on Jun. 27, 2018.

(51) Int. Cl. B24B 13/00; H01S 3/094; H01J 37/06; C23C 16/448

(52) U.S. Cl. CPC B24B 13/0037; C23C 16/448; H01J 37/06; H01S 3/094076

(57) ABSTRACT

A finishing and coating apparatus is configured for power polishing optical components. The apparatus includes a housing, a substrate holder, a vacuum pump system, a laser, and a coating source. The housing defines a chamber and the substrate holder is disposed within the chamber and configured to hold one or more optical components. The vacuum pump system is configured to create a vacuum within the chamber. The laser includes a laser engine and a laser beam delivery apparatus configured to direct a beam from the laser engine toward the one or more optical components. The laser is configured to finish the one or more optical components prior to coating the one or more optical components.

### CROSS-REFERENCE TO RELATED APPLICATIONS

This application claims priority to U.S. Provisional Application No. 62/690,514, filed, Jun. 27, 2018, the entirety of which is incorporated herein by reference.

### FIELD

This invention relates to processing of optical components and, specifically, to finishing and coating optical components.

### BACKGROUND

During manufacturing, optical components, such as lenses and mirrors, are finished to achieve the desired surface finish, appearance, and clarity. The optical components are commonly polished using labor-intensive mechanical processes using implements such as lapping tools. More recently, other means of finishing these components have been developed, including through the use of lasers.

In addition, various coatings have been used to protect the optical elements as well as to provide the desired level of transmissivity or reflectivity. These coatings include anti-reflection (AR) coatings, high reflective (mirror) coatings, beamsplitter coatings, and filter coatings. The coatings are created by depositing dielectric and metallic materials such as Tantalum Pentoxide, Silicon Dioxide and/or Aluminum Oxide in alternating layers. The coatings can be applied using a variety of processes, including physical vapor deposition, ion-beam sputtering, chemical vapor deposition, and atomic layer deposition.

### SUMMARY

In one aspect, a finishing and coating apparatus includes a housing defining a chamber, a substrate holder located within the chamber and configured to hold one or more optical components. A vacuum pump system is provided to create a vacuum within the chamber. A laser is provided that includes a laser engine and a beam delivery apparatus configured to direct the beam from the laser engine toward the one or more optical components. A coating source is employed such that the laser finishes the one or more optical components prior to coating of the one or more optical components.

In another aspect, a method of finishing and coating an optical component is provided in which an optical component is introduced into a chamber defined by a housing. A vacuum pump system is initiated to draw a vacuum within the chamber, and one or more heaters are started. A surface of the optical component is finished by directing a laser at the optical component using a beam delivery apparatus and coating is applied to the surface of the finished optical component.

In another aspect, a laser beam delivery apparatus is provided that includes a stationary portion having a longitudinal axis and configured to be mounted to a laser engine. An extendable portion having one or more guiding components is arranged so as to direct a laser beam such that the extendable portion may translate along the longitudinal axis of the stationary portion from a retracted position to an extended position.

### BRIEF DESCRIPTION OF THE DRAWINGS

The features of the embodiments described herein will be more fully disclosed in the following detailed description, which is to be considered together with the accompanying drawings wherein like numbers refer to like parts and further wherein:

FIG. 1 shows a perspective view of a finishing and coating apparatus, according to one embodiment, with the beam delivery apparatus in a retracted configuration.

FIG. 2 shows a detail view of the port in the housing of the finishing and coating apparatus of FIG. 1 with a cover over the port;

FIG. 3A shows a top view of the finishing and coating apparatus of FIG. 1;

FIG. 3B shows a side cross-sectional view of the finishing and coating apparatus of FIG. 1, taken along the plane shown in FIG. 3A;

FIG. 4 shows a detail cross-sectional view of the port of the housing of the finishing and coating apparatus of FIG. 1;

FIG. 5 shows a perspective view of the finishing and coating apparatus of FIG. 1 with the beam delivery apparatus in an extended configuration;

FIG. 6 shows a detail view of the port of the housing of the finishing and coating apparatus of FIG. 1 with the cover removed from the port;

FIG. 7 shows a side cross-sectional view of the finishing and coating apparatus of FIG. 1, taken along the plane shown in FIG. 3A, with the beam delivery apparatus in an extended configuration;

FIG. 8 shows a detail cross-sectional view of the port of the housing of the finishing and coating apparatus of FIG. 1 with the cover removed from the port and the beam delivery apparatus in an extended configuration;

FIG. 9 shows a flow diagram illustrating a method of finishing and coating an optical component;

FIG. 10 shows a housing having a plurality of chambers, according to one embodiment;

FIG. 11 shows a perspective view of a finishing and coating apparatus, according to another embodiment;

FIG. 12 shows a detail perspective view of the embodiment of FIG. 11;

FIG. 13A shows a top view of the finishing and coating apparatus of FIG. 11;

FIG. 13B shows a cross-sectional view of the finishing and coating apparatus of FIG. 11, taken along the plane shown in FIG. 13A;

FIG. 14 shows a detail cross-sectional view of the finishing and coating apparatus of FIG. 11;

FIG. 15 shows a front view of the finishing and coating apparatus of FIG. 11 in a configuration in which facets of the substrate holder are partially rotated;

FIG. 16 shows a detail view of the partially rotated facets of FIG. 15;

FIG. 17 shows a perspective view of a finishing and coating apparatus, according to another embodiment;

FIG. 18 shows a detail perspective view of the finishing and coating apparatus of FIG. 17;

FIG. 19A shows a top view of the finishing and coating apparatus of FIG. 17;

FIG. 19B shows a cross-sectional view of the finishing and coating apparatus of FIG. 17, taken along the plane shown in FIG. 19A;

FIG. 20 shows a detail cross-sectional view of the finishing and coating apparatus of FIG. 17;

FIG. 21 shows a front view of the finishing and coating apparatus of FIG. 17;

FIG. 22 shows a perspective view of a finishing and coating apparatus, according to another embodiment;

FIG. 23 shows a detail perspective view of the finishing and coating apparatus of FIG. 22;

FIG. 24A shows a top view of the finishing and coating apparatus of FIG. 22;

FIG. 24B shows a cross-sectional view of the finishing and coating apparatus of FIG. 22, taken along the plane shown in FIG. 24A;

FIG. 25 shows a detail cross-sectional view of the finishing and coating apparatus of FIG. 22;

FIG. 26 shows a bottom cross-sectional view of the finishing and coating apparatus of FIG. 22;

FIG. 27 shows a front view of a finishing and coating apparatus, according to another embodiment;

FIG. 28 shows a side cross-sectional view of the finishing and coating apparatus of FIG. 27, taken along the plane shown in FIG. 27;

FIG. 29 shows a perspective view of the finishing and coating apparatus of FIG. 27;

FIG. 30 shows a detail perspective view of the finishing and coating apparatus of FIG. 27;

FIG. 31 shows a perspective partial cross-sectional view of a finishing and coating apparatus, according to another embodiment;

FIG. 32A shows a top view of the finishing and coating apparatus of FIG. 31;

FIG. 32B shows a rear cross-section view of the finishing and coating apparatus of FIG. 31, taken along the plane shown in FIG. 32A;

FIG. 33 shows a detail view of the substrate holder of the finishing and coating apparatus of FIG. 31;

FIG. 34 shows a side cross-sectional view of the finishing and coating apparatus of FIG. 31;

FIG. 35 shows a detail side cross-sectional view of the finishing and coating apparatus of FIG. 31;

FIG. 36 shows a front view of a finishing and coating apparatus, according to another embodiment;

FIG. 37 shows a perspective, partial cross-sectional view of the finishing and coating apparatus of FIG. 36;

FIG. 38A shows a top view of the finishing and coating apparatus of FIG. 36;

FIG. 38B shows a front cross-sectional view of the finishing and coating apparatus of FIG. 36, taken along the plane shown in FIG. 38A;

FIG. 39 shows a detail view of the finishing and coating apparatus of FIG. 36; and

FIG. 40 shows a side cross-sectional view of the finishing and coating apparatus of FIG. 36, taken along the plane shown in FIG. 38A.

### DETAILED DESCRIPTION OF PREFERRED EMBODIMENTS

This description of the exemplary embodiments is intended to be read in connection with the accompanying drawings, which are to be considered part of the entire written description. The drawing figures are not necessarily to scale and certain features may be shown exaggerated in scale or in somewhat schematic form in the interest of clarity and conciseness. In the description, relative terms such as “horizontal,” “vertical,” “up,” “down,” “top” and “bottom” as well as derivatives thereof (e.g., “horizontally,” “downwardly,” “upwardly,” etc.) should be construed to refer to the orientation as then described or as shown in the drawing figure under discussion. These relative terms are for convenience of description and normally are not intended to require a particular orientation. Terms including “inwardly” versus “outwardly,” “longitudinal” versus “lateral” and the like are to be interpreted relative to one another or relative to an axis of elongation, or an axis or center of rotation, as appropriate. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise. When only a single machine is illustrated, the term “machine” shall also be taken to include any collection of machines that individually or jointly execute a set (or multiple sets) of instructions to perform any one or more of the methodologies discussed herein. The term “operatively connected” is such an attachment, coupling or connection that allows the pertinent structures to operate as intended by virtue of that relationship. In the claims, means-plus-function clauses, if used, are intended to cover the structures described, suggested, or rendered obvious by the written description or drawings for performing the recited function, including not only structural equivalents but also equivalent structures.

The present disclosure provides apparatuses and methods for laser finishing and coating optical components. The apparatuses and methods described herein allow the optical components to be finished and coated in the same housing. This provides significant benefits in terms of processing time while at the same time reducing the scrap rate of the optical components. The apparatuses and methods described herein can be used to process a variety of optical components including, but not limited to, mirrors, lenses, windows, prisms, and optical filters. The optical components can be spherical, aspherical, prismatic or have any other appropriate geometry. The optical components can be constructed from any appropriate material including, but not limited to, silica, quartz, ceramic, optical glass, filter glass, low expansion glass, amorphous glass, and crystalline materials. The apparatuses and methods described herein can be used to apply any appropriate coating, including, but not limited to, antireflective coatings, polarizing coatings, high-reflective coatings, beamsplitter coatings, optical filter coatings, ultraviolet coatings, and transparent conductive coatings.

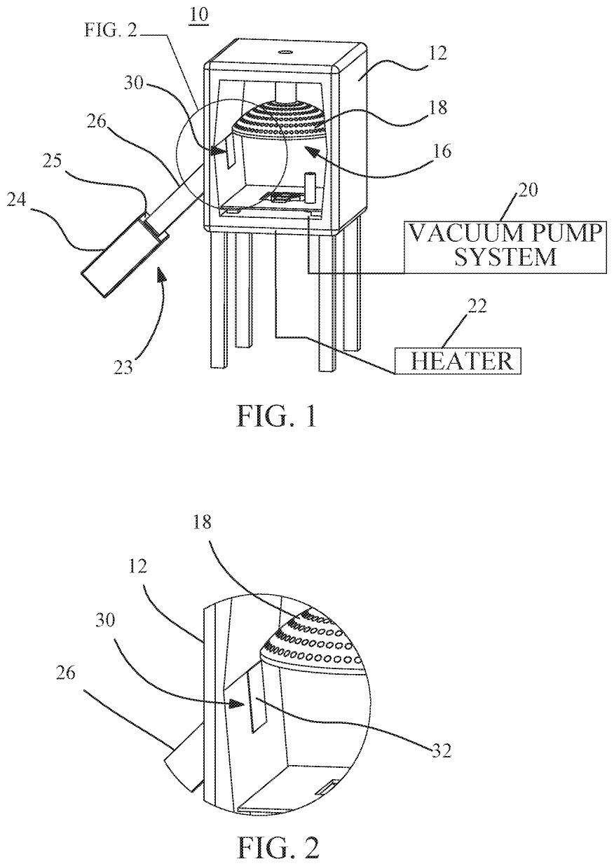

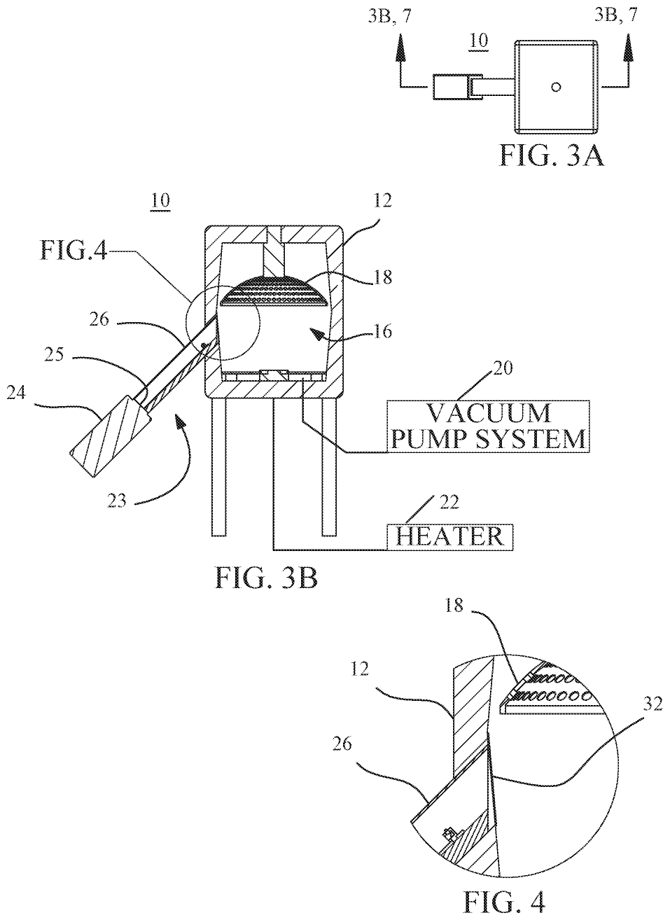

As seen in FIG. 1, in one embodiment, a finishing and coating apparatus 10 includes a housing 12 with a door (not shown) that allows optical components to be loaded into a chamber 16 defined by the housing 12. The finishing and coating apparatus 10 includes a substrate holder 18 upon which optical components can be placed for processing. The substrate holder 18 can be, for example, a stationary substrate holder. In other embodiments, the substrate holder 18 is capable of rotating the optical components during finishing and/or coating, as will be described further herein. The substrate holder 18 can be any appropriate shape. For example, as shown in FIGS. 1-8, the substrate holder 18 can be dome or calotte shaped. In other embodiments, the substrate holder 18 is planar. The substrate holder 18 can include any appropriate tooling to retain the optical components in place. For example, in one embodiment, two-piece tooling is used to sandwich the optical components. Alternatively, the substrate holder can include recesses configured to receive the optical components. In such an embodiment, the recesses are configured such that gravitational forces acting on the optical components act to retain the optical components within the recesses, the recesses thereby restricting movement of the optical components. The finishing and coating apparatus 10 can further include a vacuum pump system 20 which is able to pull a vacuum within the chamber 16. The vacuum pump system 20 can be configured to establish a vacuum within the chamber of any appropriate pressure. In one embodiment, the vacuum pump system 20 is configured to establish a vacuum in the chamber 16 with a pressure of 10⁻⁶ mbar or less. In one embodiment, the vacuum pump system 20 includes a turbopump and a cryogenic pump. The finishing and coating apparatus 10 can further include one or more heaters 22 configured to heat the optical components or the chamber 16.

The polishing and coating apparatus 10 also includes a finisher 23 having a laser engine 24 and a beam delivery apparatus 26. The beam delivery apparatus 26 is configured to direct the laser at the optical components and condition the laser beam shape and energy distribution to achieve the desired surface treatment. The laser engine 24 and the beam delivery apparatus 26 are used to finish the surfaces of the optical components to reduce the surface roughness of the surfaces and to remove imperfections such as scratches and digs. The finisher 23 can heat and/or ablate the surface to improve the surface finish thereof. Specifically, the finisher 23 can be used to heat the surface of the optical component, allowing the surface material to flow, in response to gravity and surface tension, to fill imperfections in the surface of the optical component. The finisher 23 can also be used for ablation to remove material from the surface of the optical components. Heating and ablation can be performed together or, alternatively, independently. As used herein, finishing refers to heating, ablating, or combinations of heating and ablating, the surface of the optical component as well as any other mechanism by which a laser can be used to alter the surface of an optical component.

The laser polishing beam can be directed by one or more galvanometer (galvo) mirrors, Risley Prisms, or other scanning apparatus. For example, by adjusting the orientation of one or more galvo mirrors, the beam can be “steered” along the surface of the optical components. Additionally, or alternatively, a portion of the beam delivery apparatus 26 can be movable within the chamber 16 such that the beam delivery apparatus 26 can be aligned with any one of the optical components, as will be described more fully herein.

The laser engine 24 can be positioned outside the housing 12 or within the chamber 16. In one embodiment, as shown in FIGS. 1-8, the laser engine 24 is positioned outside the housing 12. During finishing, the beam produced by the laser engine 24 passes into the beam delivery apparatus 26 through, for example, an infrared window 25.

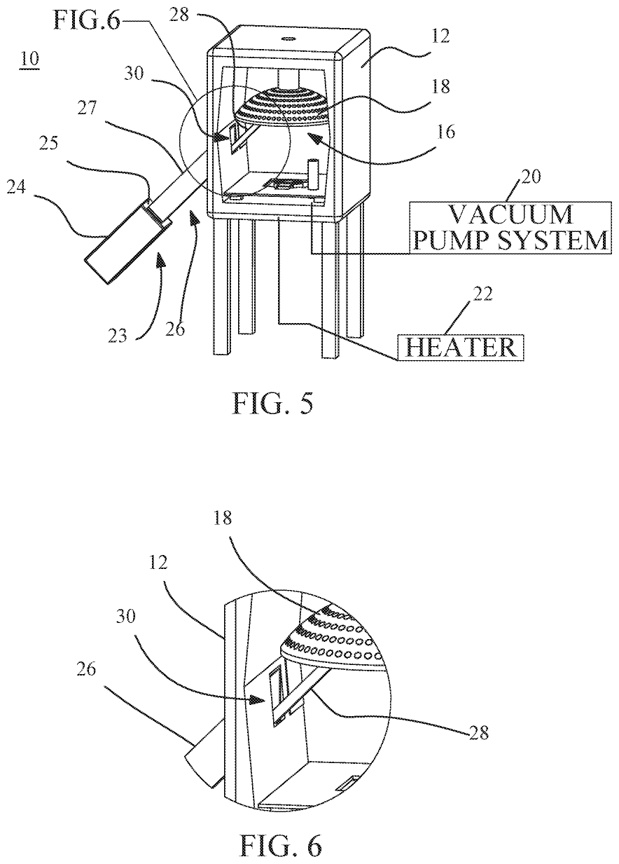

In one embodiment, the beam delivery apparatus 26 includes a stationary portion 27 and an extendable portion 28 (shown in FIG. 5). The stationary portion 27 is aligned with a port 30 of the housing 12. As shown best in FIGS. 1 and 2, when finishing is not being performed, the port 30 can be fully or partially closed by a cover 32. The cover 32 ensures that during the coating process material does not enter or cover the stationary portion 27 or the extendable portion 28. Movement of the cover 32 can be performed manually or automatically. In one embodiment, the cover 32 is engaged with the extendable portion 28 of the beam delivery apparatus 26. Hence, when the extendable portion 28 is retracted and housed within the stationary portion 27, the cover 32 fully or partially covers the port 30.

The stationary portion 27 is mounted to the housing 12 such that when the door of the housing is closed, a closed and sealed volume is formed within the housing 12 and the stationary portion 27. As a result, when a vacuum is established in the chamber 16, the volume within the stationary portion 27 is evacuated as well. A sealant can be used around the perimeter of the port 30 to restrict the passage of air between the stationary portion 27 and the port 30.

One or more galvo mirrors, Risley Prisms, or other scanning apparatus may be mounted within, or coupled to, the extendable portion 28 to guide the beam along the surface of the optical components. In various embodiments, the extendable portion 28 includes a focus adjustment (i.e., a physical or lens based adjustment) to control the position of the laser on the part being processed. In various embodiments, the laser is directed toward the part being processed using a galvo mirror and the field curvature of the galvo mirror is selected to complement the curvature of the substrate holder 18. This may provide for faster processing of the optical components.

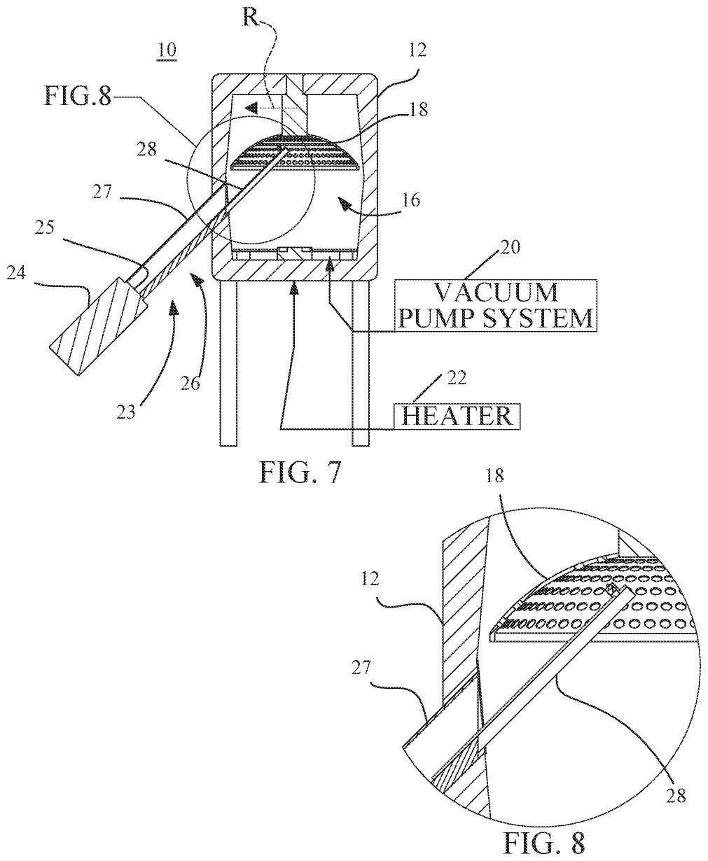

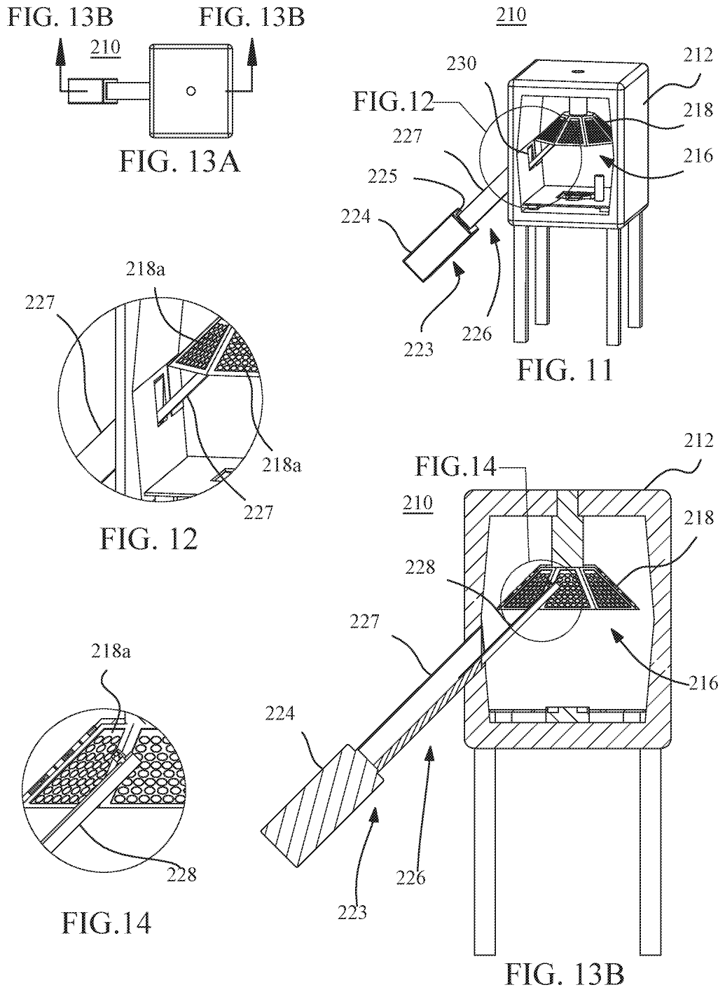

Further, the extendable portion 28 is movable within the stationary portion 27 and in and out of the stationary portion 27 such that it can scan along the substrate holder 18. The extendable portion 28 can be retracted and extended through any appropriate means. For example, the extendable portion 28 can be coupled to a lead screw that allows for extension and retraction of the extendable portion 28 and an appropriate feedback control loop for control of the motion of the extendable portion 28. The extendable portion 28 is configured to translate such that it can traverse along a radius ‘R’ of the substrate holder 18 (shown in FIG. 7). The substrate holder 18 is configured to rotate to align a different set of optical components with the extendable portion 28. The substrate holder 18 may have a curved shape, and in some embodiments a paraboloid shape, such that the optical components are assembled from the interior surface of the paraboloid shaped substrate holder 18. The interior of the substrate holder 18 can have a continuous curvature or, alternatively, can be faceted (as shown in FIGS. 11-14). Because the optical components are assembled inside the paraboloid, they are at an angle with respect to the axis of rotation of the substrate holder 18. This places them at an angle that is accessible to the extendable portion 28 of the beam delivery apparatus 26.

Although illustrated as a single extendable portion 28, multiple stages of extension may be used. Such embodiments may allow for increased positional accuracy of the beam on the part being processed. For example, a first stage may provide for coarse adjustment of the beam, while a second stage may provide for finer adjustment. The galvo mirrors and other scanning apparatus may be mounted to the second stage providing for fine adjustment of the position of the beam.

For example, in one embodiment, the beam delivery apparatus 26 is initially positioned such that the beam is located toward the center of the substrate holder 18 such that it can finish optical components mounted nearer the center. The beam delivery apparatus 26 then moves outward (retracted into the stationary portion 27) and guides the beam along a radius of the substrate holder 18 to finish optical components mounted along the radius. As the beam traverses along the radius it finishes portions of the optical components that are within its field of coverage (i.e., the width or portion of the substrate holder's circumference that can be reached by the beam). When the beam reaches the outer portion of the substrate holder 18, the substrate holder 18 is then incrementally rotated. The rotation increment is equal to or less than the field of coverage of the beam delivery apparatus 26. For example, in one embodiment, the substrate holder 18 is rotated an amount equal to 80% of the field of coverage of the beam delivery apparatus 26. This ensures that the beam is able to reach all portions of the optical components. The beam delivery apparatus 26 then traverses the beam back toward the center of the substrate holder 18 while finishing the portions of the optical components within the field of coverage. When the beam reaches the center of the substrate holder 18 the substrate holder 18 is once again incrementally rotated. This process can be continued until all optical components have been finished.

The rate of movement of the laser across the surfaces of the optical components can be varied to provide the desired surface finish. In addition, the beam delivery apparatus can cause the beam to dwell in an area of the optical component for a predefined duration. Alternatively, one or more monitors can be used to determine whether the surface of an optical component has achieved the desired finish prior to moving the laser to another component. For example, one or more optical monitors can be used. Also, beam delivery apparatus 26 may incorporate structures or systems that are suited for adjusting the focus of the beam as it traverses an optical component. For example, in some embodiments, the beam path may follow the curvature of the part being processed through the use of focus adjusting optical components associated with beam delivery apparatus 26.

The laser engine 24 can be a CO₂ laser device, an argon-fluoride (ArF) excimer laser device, a neodymium-doped yttrium aluminum garnet (Nd-YAG) solid state laser device, electron beam gun, or any other appropriate laser device. The laser engine 24 can have any appropriate power. In one embodiment, the power is between 50 Watts and 2000 Watts. In addition, the spot size produced by the laser can be any appropriate value. In one embodiment, the spot size is between 200 micrometers and 5 millimeters. The laser engine may produce a continuous wave or be pulsed at any appropriate rate (e.g., between 1 and 100 kHz). In various embodiments, the system includes more than one laser engine. For example, in one embodiment, an ultrafast laser is used to ablate the surface of the optical components and a CO₂ laser is used to finish the optical components using thermal evaporation.

The finishing and coating apparatus 10 further includes a coating source. The finishing and coating apparatus 10 can use any appropriate coating method. For example, the finishing and coating apparatus 10 can use physical vapor deposition techniques such as, for example evaporative deposition (e.g., thermal evaporative deposition and electron gun deposition). Alternatively, the finishing and coating apparatus 10 can use sputtering techniques such as, for example ion beam sputtering or plasma sputtering. Alternatively, the finishing and coating apparatus 10 can use chemical vapor deposition techniques such as, for example, atomic layer deposition.

In one embodiment, the coating source includes an evaporation body. In such an embodiment, the finishing and coating apparatus 10 may further include an electron gun. During the coating process, the electron gun is directed toward the evaporation body, thereby causing the evaporation body to melt or sublimate and causing the material from the evaporation body to transform into a vapor phase that can be deposited on the optical components. In at least one embodiment, the finishing and coating apparatus 10 includes an ion gun that is configured to bombard the optical components with energetic ions to further improve the resultant coating, such as by increasing the density of the coating.

In another embodiment, a sputtering coating process is used. In such an embodiment, the coating source includes a sputtering target. The finishing and coating apparatus can further include an ion or atom source, such as an ion gun, configured to bombard the sputtering target to free the target material from the sputtering target such that the target material can be deposited on the optical components.

In another embodiment, the coating source includes a gas delivery system. The gas delivery system is used to introduce a source gas into the chamber to coat the optical components. The source gas may be introduced to the chamber along with a carrier gas to facilitate transport of the source gas and coating of the optical components. Such an embodiment can be used for chemical vapor deposition or atomic layer deposition of the optical components.

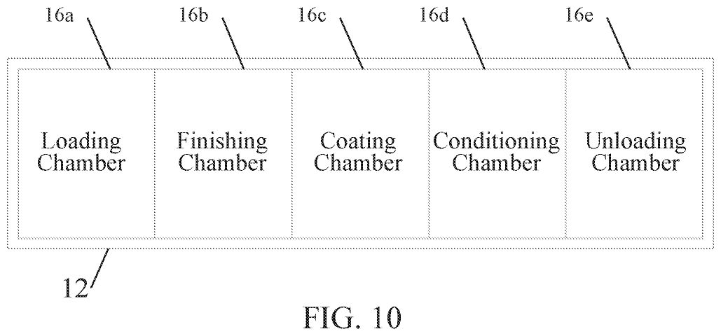

As shown in FIG. 10, in one embodiment, the housing 12 defines a plurality of chambers. For example, in one embodiment, the housing 12 includes a finishing chamber 16b and a coating chamber 16c. The finishing chamber 16b can be separated from the coating chamber 16c by a divider. In such embodiments, the finishing process can be carried out in the finishing chamber 16b and the coating process can be carried out in the coating chamber 16c. As a result, any particles or debris created during the finishing process can be isolated in the finishing chamber 16b, thereby further improving the quality of the coating. The optical components can be transported from the finishing chamber 16b to the coating chamber 16c using an automated material handling system.

The divider can include a wall between the finishing chamber 16b and the coating chamber 16c. The divider can also include a door that is configured, when closed, to seal the finishing chamber 16b from the coating chamber 16c. In one embodiment, the divider is a load lock door to fully isolate the chambers.

In another embodiment, a loading chamber 16a and an unloading chamber 16e are provided in addition to the finishing chamber 16b and the coating chamber 16c. The loading chamber 16a can be connected to the finishing chamber 16b via, for example, a load lock door. Similarly, the unloading chamber 16e can be connected to the conditioning chamber 16d via, for example, a load lock door. As such, the vacuum within the loading 16a and unloading 16e chamber can be cycled, to allow components to be added or removed, without disturbing the vacuum within the finishing 16b and/or coating 16c chambers. It should be understood that, although the loading 16a and unloading 16e chambers are shown as separate chambers, in at least one embodiment, the optical components are loaded and unloaded from a single chamber.

Further, in one embodiment a conditioning chamber 16d is provided that may be connected to the coating chamber 16c. After coating, the optical components can be moved into the conditioning chamber 16d where the coating is conditioned. In one embodiment, the conditioning is performed using an additional laser engine and beam delivery apparatus. Alternatively, after coating, the optical components can be moved back into the finishing chamber 16b and the coatings are conditioned using the same laser engine and beam delivery apparatus used to finish the optical components prior to coating. During conditioning, the laser can be operated at a lower power or energy than used during the finishing process. The conditioning can increase the quality of the coating.

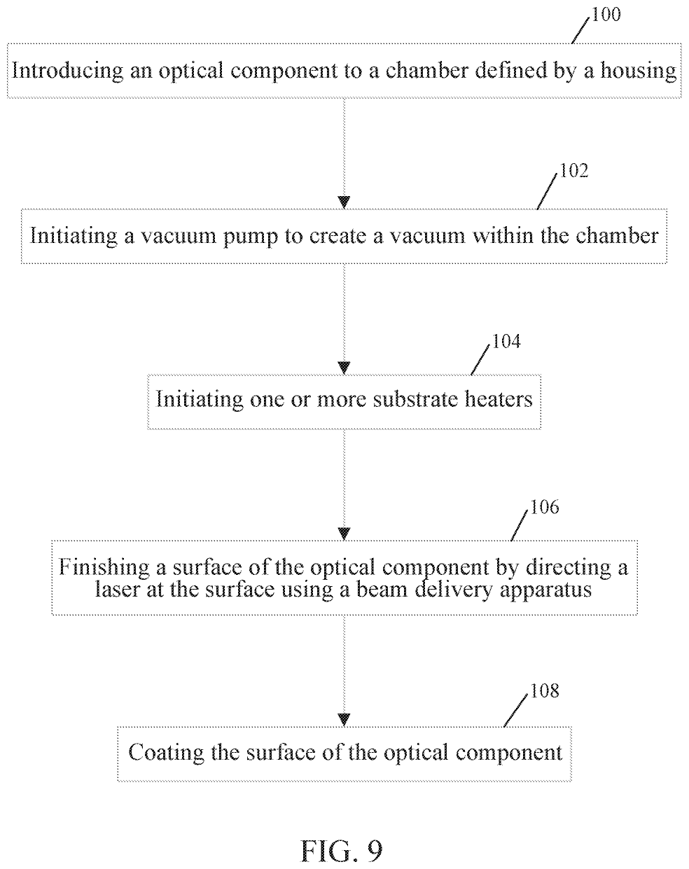

In another embodiment, shown in FIG. 9, a method of processing an optical component is provided. The method includes, at step 100, introducing the optical component into the chamber 16. After loading the optical components into the chamber 16, the vacuum pump system 20 may be initiated to reduce the pressure within the chamber 16 at step 102. In addition, the one or more heaters 22 may be initiated to increase the temperature within the chamber 16 at step 104. The method further includes finishing the optical components with the finisher 23 at step 106. The finishing step 106 can be performed with the chamber fully evacuated. Alternatively, the finishing step 106 can be performed with the chamber partially evacuated (i.e., to a pressure below atmospheric pressure but higher than the pressure used during the subsequent coating step) or the finishing step 106 can be performed prior to evacuating the chamber. The method further includes, after the finishing step, coating the optical components at step 108. As described above, any appropriate coating process can be used. After the coating step is complete, the chamber 16 is allowed to return to atmospheric pressure and cooled from its elevated temperature. The optical components can then be removed from the chamber 16.

In one embodiment, the method further includes, after applying the coating, conditioning the coating by directing the laser at the optical component. During this step, the laser may be operated at a lower energy than is used during the finishing step.

In one embodiment, the finishing step includes performing a raster scan over the surface of each of the optical components. The rate of movement of the laser over the surface can be tailored to provide the desired amount of heating and/or ablation of the glass surface.

In one embodiment, the method further includes inspecting the surface of the optical component after the finishing step. The finishing step can also include performing one or more secondary finishing steps in order to more fully refine the surface of the optical component.

In one embodiment, the optical components are mechanically polished prior to being introduced to the chamber 16. The mechanical polishing step can be used to remove larger surface imperfections or irregularities.

In one embodiment, the optical component is rotated during the finishing and/or coating step. The optical component can be rotated at any appropriate rate including 36 revolutions per minute.

Because the finishing step can be completed, at least partially, during evacuation and heating of the chamber 16, the finishing step adds minimal time to the processing of the optical components. As such, the surface roughness and quality of the optical components can be increased without a reduction in throughput. The apparatuses and methods described herein also reduce the need for manual inspection which further reduces processing time and required handling. The apparatuses and methods described herein also may reduce or eliminate mechanical polishing steps.

In addition, the laser polishing step may improve the surface quality of otherwise unacceptable components such that they are acceptable for use. In this way, the scrap rate of the production of the components is reduced. Laser polishing is capable of eliminating significantly larger imperfections than other non-contact polishing techniques and, therefore, has the potential of eliminating significantly larger imperfections. The resultant surfaces have improved surface quality and can reach the surface quality achieved with superpolishing or magnetorheological finishing.

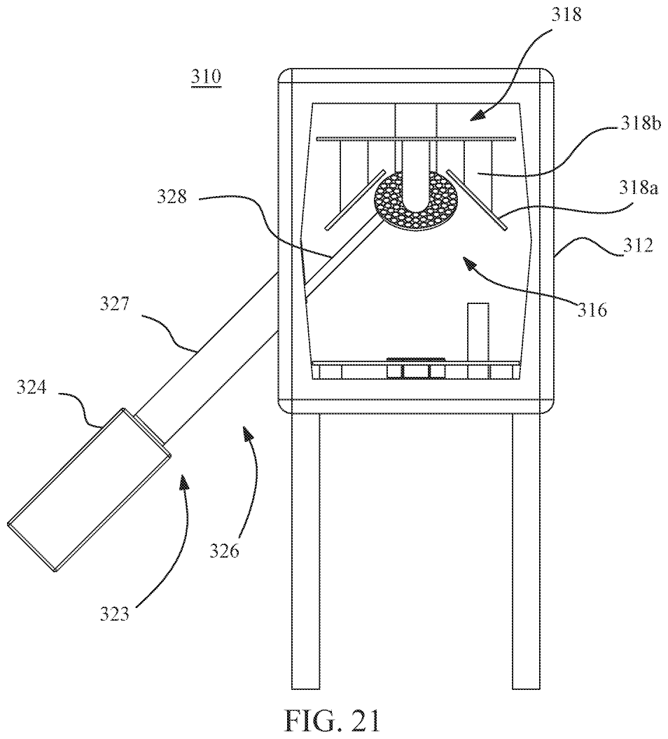

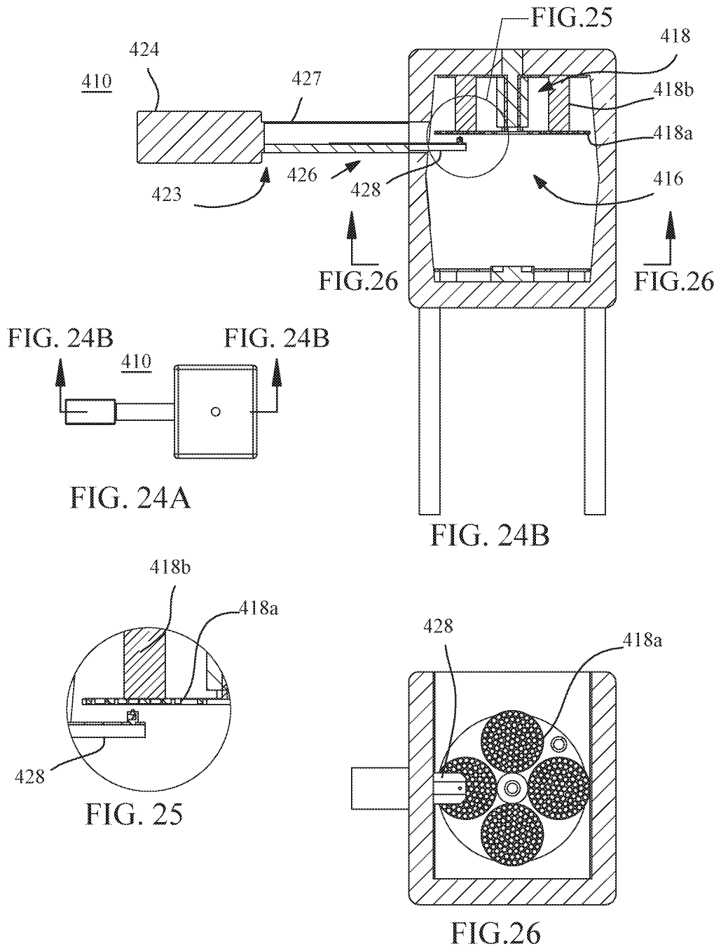

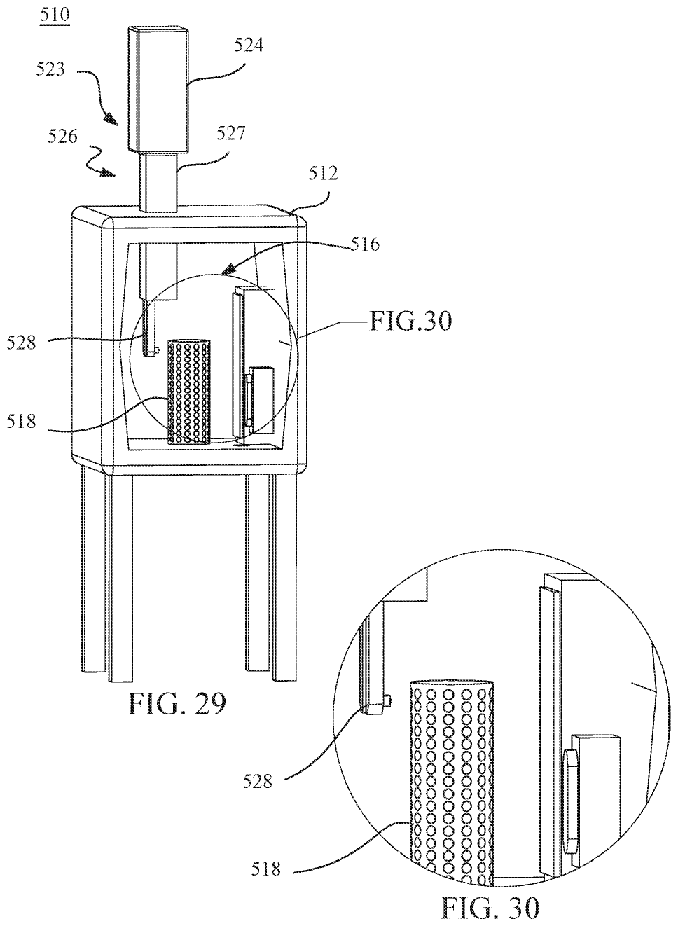

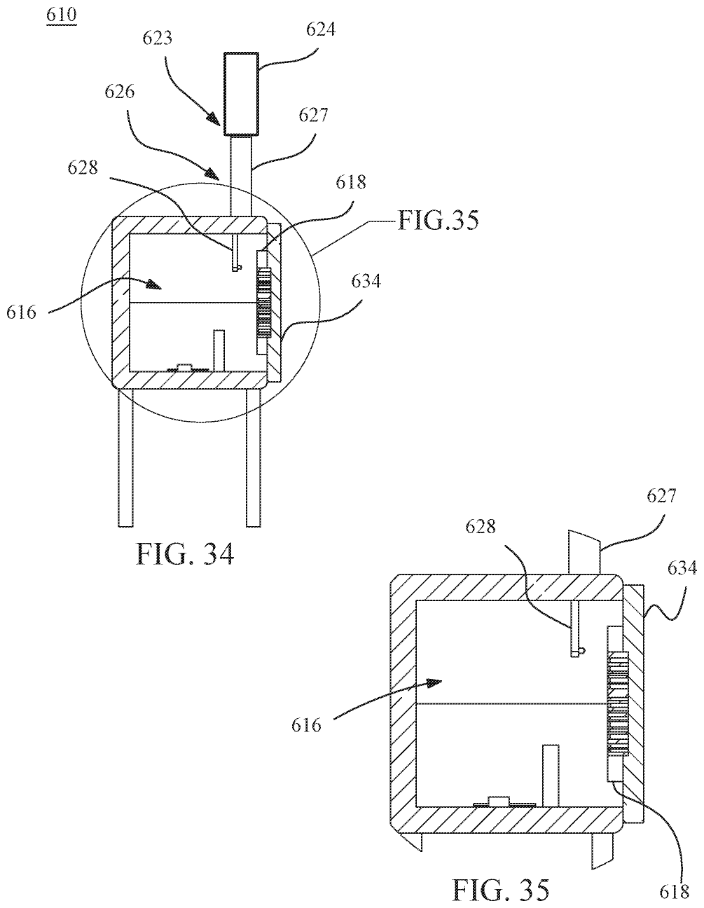

The finisher and the substrate holder can be provided in a number of configurations and orientations. FIGS. 11-35 provide several exemplary embodiments. In these figures and the accompanying description, a leading digit has been added to the reference numbers used in FIGS. 1-10 (e.g., 27, 227, 327, etc.). While these features or aspects of the embodiments described below may be similar to the description above, they need not be identical. In addition, features of the various embodiments can be combined. Furthermore, the embodiments of FIGS. 11-35 can include features or components shown or described with reference to FIGS. 1-10 and not shown in FIGS. 11-35 (e.g., the vacuum pump system and heater) and vice versa.

FIGS. 11-16 show a finishing and coating apparatus 210 wherein the substrate holder 218 is a faceted calotte. Each of the facets 218a of the substrate holder 218 are configured to support and retain a plurality of optical components. As shown, for example, in FIG. 13B, the finisher 223 passes through the wall of the housing 212 such that the extendable portion 228 can align with a facet 218a. The substrate holder 218 is configured to rotate about its central axis such that the substrate holder 218 can be incremented to align each facet with the extendable portion 228. The substrate holder 218 can be rotated in smaller increments to align specific portions of the individual facets with the extendable portion 228. Alternatively, or additionally, the extendable portion 228 can also be movable side-to-side within the stationary portion 227 to align the extendable portion 228 with the desired optical components. The substrate holder 218 can include any number of facets 218a (e.g., four facets, five facets, six facets, seven facets, eight facets)

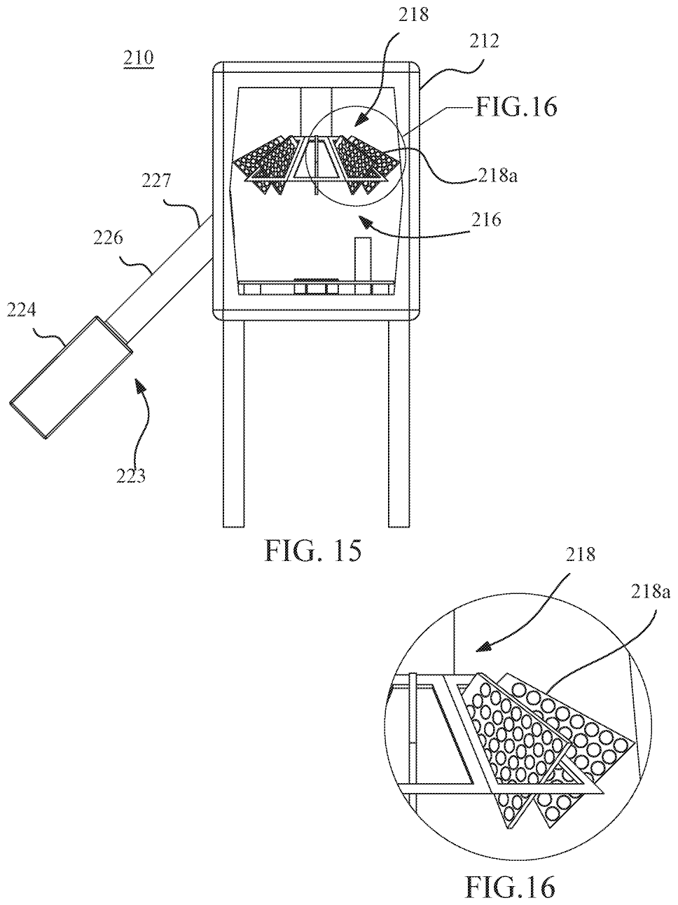

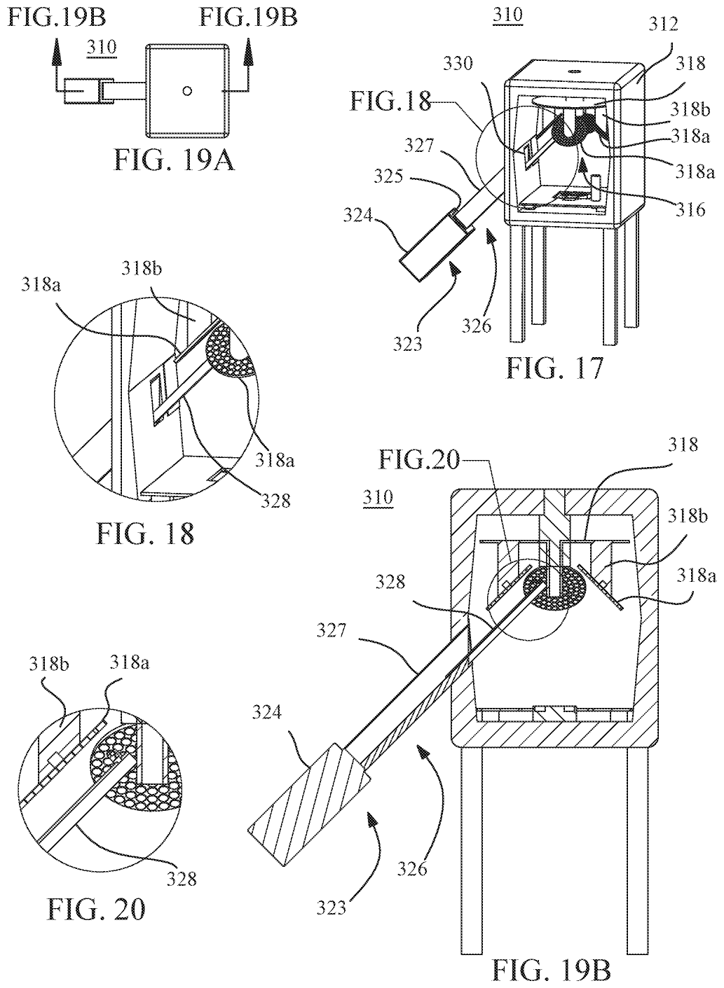

In one embodiment, as shown in FIGS. 15 and 16, the facets 218a are rotatable about an axis of the facet 218a. This rotation allows the optical components to be oriented such that either the first side or the second of the optical component is facing the coating source. This may allow optical components on different facets 218a to be coated independently or, alternatively, for opposite sides of an optical component to be coated without manual repositioning of the optical components. In other words, with a facet in a first position, the first side of the optical component is facing the coating source and a desired coating can be applied to the first surface. After coating of the first surface is completed, the facet can be rotated such that the second side of the optical component is facing the coating source, thereby allowing the desired coating to be applied to the second surface. This process can minimize the total processing time of the components. In another embodiment, as shown in FIGS. 17-21, a finishing and coating apparatus 310 includes a substrate holder 318 in the form of tilted planets 318a. The planets 318a are configured to spin independently about their own axis in addition to the substrate holder 318 rotating about its central axis. The planets 318a are rotated to align optical components with the extendable portion 328 of the beam delivery apparatus 326. The substrate holder 318 includes a plurality of support arms 318b, each support arm 318b supporting a planet 318a. The substrate holder 318 can include any number of planets 318a and support arms 318b. For example, the substrate holder 318 can include four planets 318a and support arms 318b. In another embodiment, the substrate holder 318 can include six planets 318a and support arms 318b. In another embodiment, the substrate holder 318 can include three planets 318a and support arms 318b. While the planets 318a are illustrated as circular, the planets 318a can be any appropriate shape (e.g., rectangular or triangular). In addition, the planets 318a can be tilted at any appropriate angle. For example, the planets 318a can be between 30° and 60° from horizontal. In another embodiment, the planets 318a are between 15° and 75° from horizontal.

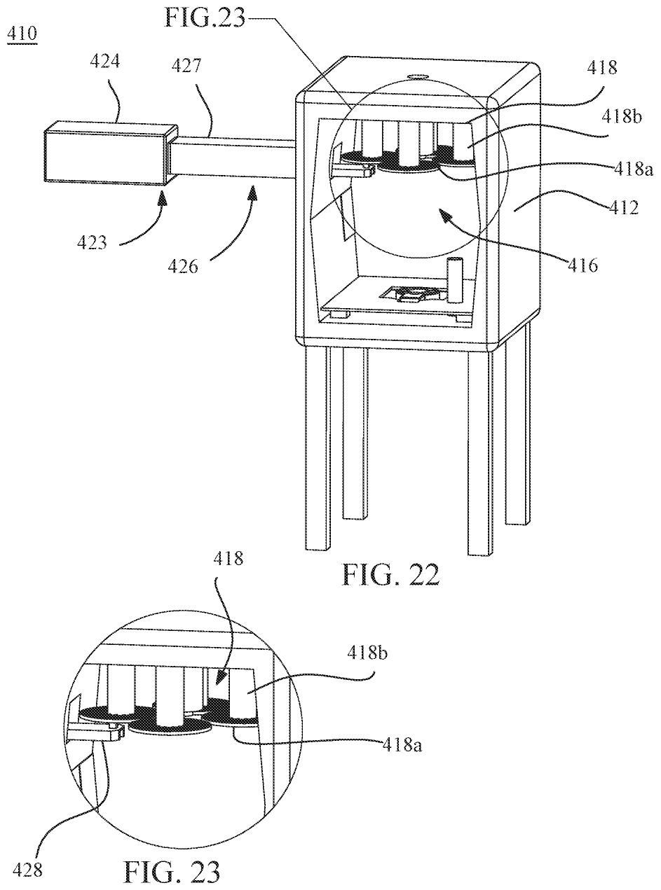

In another embodiment, as shown in FIGS. 22-26, a finishing and coating apparatus 410 includes a substrate holder 418 in the form of flat planets 418a. Each of the planets 418a is mounted to a support arm 418b. In such an embodiment, the finisher 423 is mounted such that the extendable portion 428 is parallel to the planets 418a. The substrate holder 418 is rotatable such that each planet 418a can be positioned in the finishing position. For example, as shown in FIG. 26, the planet that is in the “9 o'clock” position is aligned with the end of the extendable portion 428. The planet that is in the “9 o'clock” position is rotated about an axis to align certain optical components with the end of the extendable portion 428. As described above, the planets 418a can be any appropriate shape and the substrate holder 418 can include any number of planets 418a.

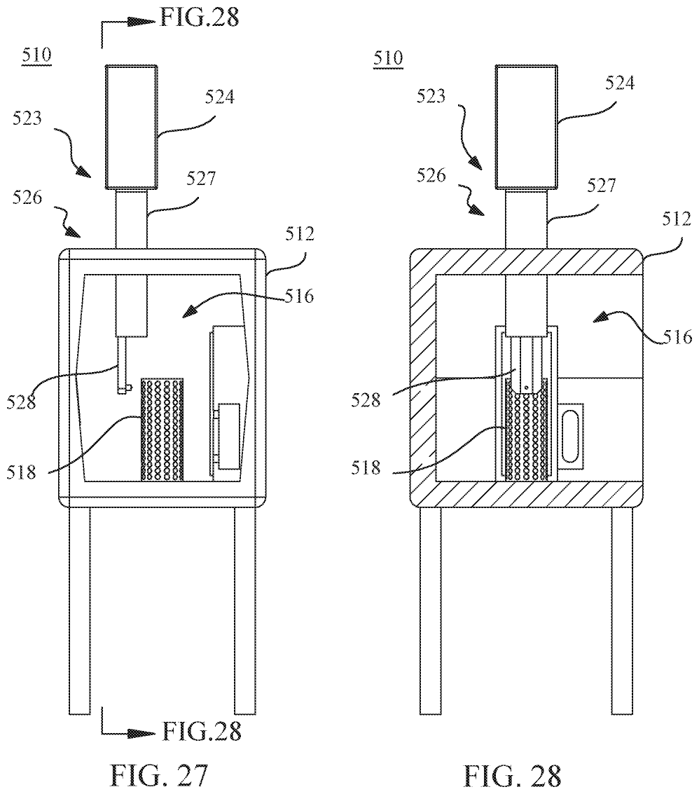

In another embodiment, as shown in FIGS. 27-30, a finishing and coating apparatus 510 includes a cylindrical substrate holder 518. The optical components are mounted around the outer surface of the substrate holder 518. The finisher 523 is mounted such that the extendable portion 528 is parallel to the longitudinal axis of the substrate holder 518. The optical components are arranged on the substrate holder 518 in a line parallel to the longitudinal axis of the substrate holder 518. Hence, the extendable portion 528 is moved parallel to the longitudinal axis of the substrate holder 518 to finish a single line of optical components. The substrate holder 518 is then rotated to align another line of optical components to allow finishing of the next line of optical components. This is continued until each of the optical components is finished. In one embodiment, the coating source is on the opposite side of the substrate holder 618 as the extendable portion 528 of the beam delivery apparatus 526.

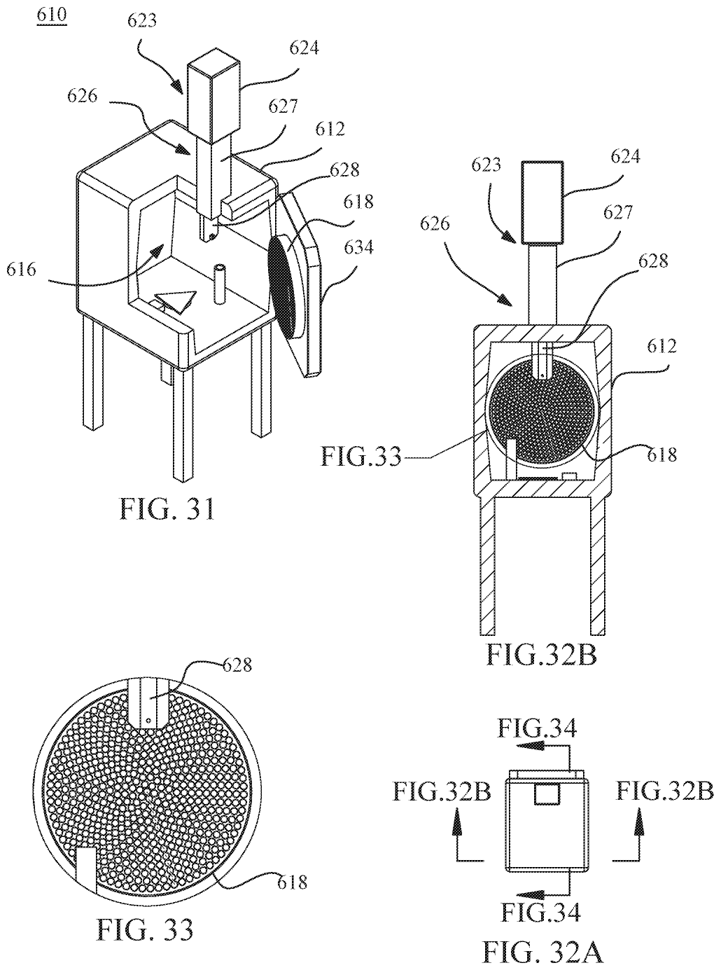

In another embodiment, as shown in FIGS. 31-35, a finishing and coating apparatus 610 includes a substrate holder 618 in the form of a plate. In at least one embodiment, the substrate holder 618 is mounted to the door 634 of the housing 612. Mounting the substrate holder 618 to the door 634 allows for simplified loading and unloading of the optical components. The finisher 623 is mounted such that the extendable portion 628 extends parallel to the surface of the substrate holder 618 upon which the optical components are mounted. The substrate holder 618 is rotatable about an axis, for example its central axis, to align each optical component with the extendable portion 628. The optical components can be positioned along radial lines on the substrate holder 618. Hence, rotation of the substrate holder 618 incrementally aligns radially positioned optical components with the extendable portion 628 of the beam delivery apparatus 626.

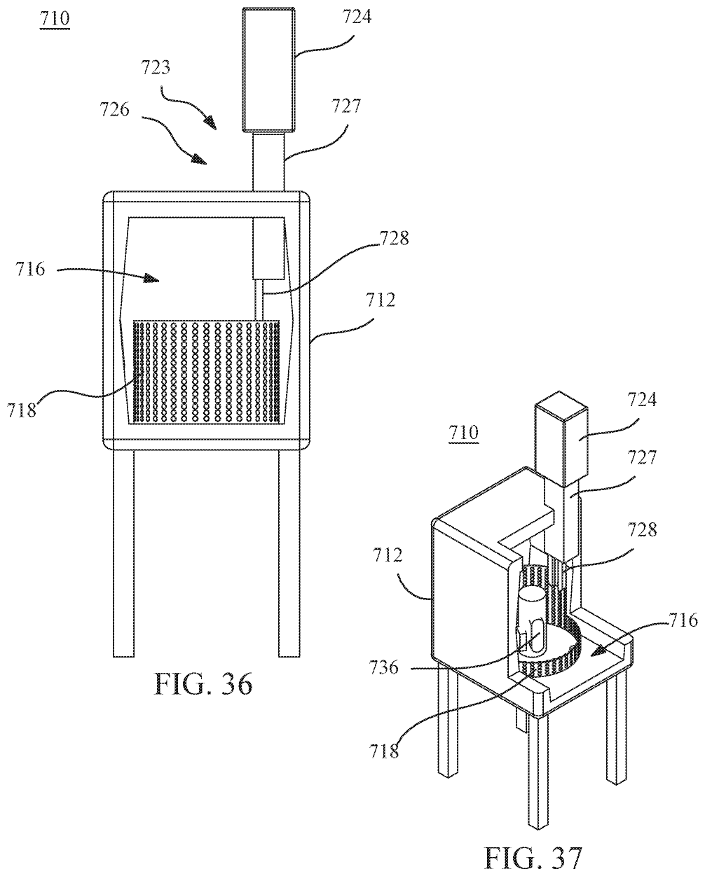

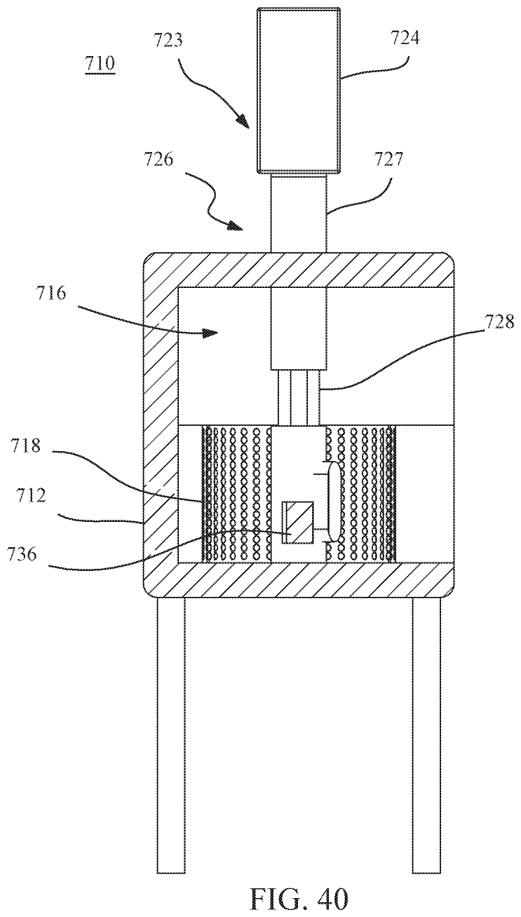

In another embodiment, as shown in FIGS. 36-40, a finishing and coating apparatus 710 includes a cylindrical substrate holder 718 in which the optical components are mounted on an interior surface of the substrate holder 718. The finisher 723 is mounted such that the extendable portion 728 extends parallel to the longitudinal axis of the substrate holder 718. As shown best in FIGS. 37 and 40, a coating source 736 is disposed within the cylindrical substrate holder 718.

In use, the nozzle 738 of the finisher 723 is aligned with one or more optical components. The extendable portion 728 is moved in and out of the stationary portion 724 to finish optical components along the length of the cylindrical substrate holder 718. The substrate holder 718 is then rotated to align another set of optical components with the finisher 723 and the process is repeated. This can be repeated until all optical components are finished.

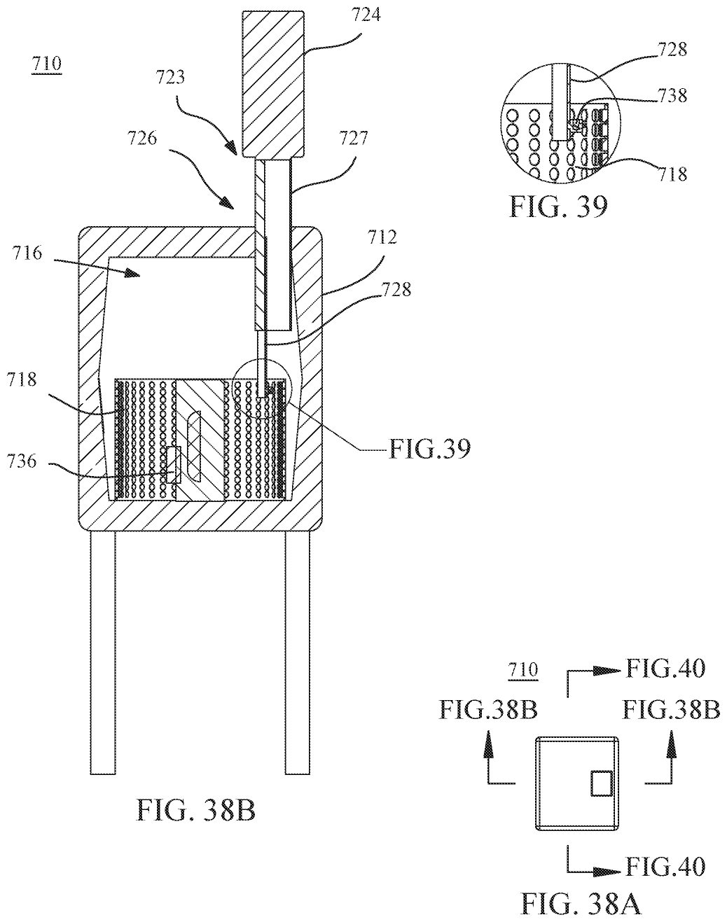

In one embodiment, after finishing, the extendable portion 728 is retracted fully and the optical components are coated using the coating source 736. In another embodiment, coating of certain optical components mounted on the substrate holder 718 is performed concurrently with finishing of other optical components mounted on the substrate holder 718. For example, as shown in FIG. 38B, the nozzle 738 of the finisher 723 can point in a first direction and the coating source 736 is oriented such that it is directed at optical components mounted on another portion of the substrate holder 718. In one embodiment, the nozzle 738 of the finisher 723 and the coating source 736 are directed in opposing, 180° offset directions. In other embodiments, the nozzle 738 and the coating source 736 are directed at different angles relative to one another, such as 90° or 135°.

Although in certain illustrated embodiments the substrate holder is mounted in an upper portion of the chamber such that the laser is directed, by the beam delivery apparatus, upward toward the optical components during the finishing process, it should be understood that, in other embodiments, the orientation is reversed. In other words, at least a portion of the beam delivery apparatus is positioned above the substrate holder such that the beam is directed downward toward the optical components.

Although the subject matter has been described in terms of exemplary embodiments, it is not limited thereto. Rather, the appended claims should be construed broadly, to include other variants and embodiments, which may be made by those skilled in the art.

What is claimed is:

1. A finishing and coating apparatus comprising:
a housing defining a chamber;
a substrate holder disposed within the chamber configured to hold one or more optical components;
a vacuum pump system configured to create a vacuum within the chamber;
a laser comprising:
a laser engine; and
a laser beam delivery apparatus configured to direct a beam from the laser engine toward the one or more optical components; and
a coating source;
wherein the laser is configured to finish the one or more optical components prior to coating of the one or more optical components.

2. The finishing and coating apparatus of claim 1, wherein the coating source includes a coating body and the finishing and coating apparatus includes an electron gun, the electron gun configured to bombard the coating body to transform a portion of the coating body to a vapor phase to coat the one or more optical components.

3. The finishing and coating apparatus of claim 1, wherein the coating source includes a sputtering target and the finishing and coating apparatus includes an ion gun, the ion gun configured to direct ions at the sputtering target to eject material from the sputtering target to coat the one or more optical components.

4. The finishing and coating apparatus of claim 1, wherein the coating source includes a gas delivery system.

5. The finishing and coating apparatus of claim 1, wherein the beam delivery apparatus comprises a stationary portion and an extendable portion.

6. The finishing and coating apparatus of claim 5, wherein the extendable portion defines a longitudinal axis, and wherein the substrate holder defines a planar surface, the one or more optical components being arranged on the planar surface, the planar surface and the longitudinal axis being parallel.

7. The finishing and coating apparatus of claim 1, wherein the housing includes a plurality of chambers.

8. The finishing and coating apparatus of claim 7, wherein each of the plurality of chambers is separated from an adjacent chamber by a load lock.

9. The finishing and coating apparatus of claim 1, wherein the substrate holder includes a plurality of facets, each of the plurality of facets configured to hold one or more optical components, and wherein the substrate holder is rotatable to align one of the plurality of facets with a portion of the laser beam delivery apparatus.

10. The finishing and coating apparatus of claim 1, wherein the substrate holder includes a plurality of planets, each of the plurality of planets configured to hold one or more optical components, and wherein the substrate holder is rotatable to align one of the plurality of planets with a portion of the laser beam delivery apparatus and each of the plurality of planets is additionally rotatable to align a desired portion of the planet with the portion of the laser beam delivery apparatus.

11. The finishing and coating apparatus of claim 10, wherein each of the plurality of planets defines an oblique angle with a rotational axis of the substrate holder.

12. The finishing and coating apparatus of claim 1, wherein the substrate holder is cylindrical and the one or more optical components are positioned on an outer surface of the substrate holder.

13. The finishing and coating apparatus of claim 1, wherein the substrate holder is mounted to a door of the housing.

14. A method of finishing and coating an optical component, comprising:
introducing an optical component into a chamber defined by a housing;
initiating a vacuum pump system to create a vacuum within the chamber;
initiating one or more heaters;
finishing a surface of the optical component by directing a laser at the optical component using a beam delivery apparatus; and
coating the surface of the optical component.

15. The method of claim 14, further comprising, after the coating step, conditioning the coating by directing the laser at the optical component using the beam delivery apparatus.

16. The method of claim 15, wherein the laser has a first power during the finishing step and a second power during the conditioning step, the first power being greater than the second power.

17. The method of claim 14, further comprising rotationally incrementing a substrate holder that holds the optical component.

18. A laser beam delivery apparatus, comprising:
a stationary portion having a longitudinal axis, the stationary portion configured to be mounted to a laser engine, and
an extendable portion having one or more guiding components configured to direct a laser beam,
wherein the extendable portion is configured to translate along the longitudinal axis of the stationary portion from a retracted position to an extended position.

19. The laser beam delivery apparatus of claim 18, wherein the beam delivery apparatus includes an infrared window at a proximal end of the stationary portion.

20. The laser beam delivery apparatus of claim 18, wherein the extendable portion is further configured to translate relative to the stationary portion along one or more axes that are perpendicular to the longitudinal axis.
